(19) United States
(12) Patent Application Publication
(10) Pub. No.: US 2010/0130014 A1
(43) Pub. Date: May 27, 2010

(54) TEXTURING MULTICRYSTALLINE SILICON

(75) Inventors: Kenta Nakayashiki, Sandvika (NO); Baomin Xu, San Jose, CA (US); Scott A. Elrod, La Honda, CA (US)

Correspondence Address: BEVER, HOFFMAN & HARMS, LLP, 901 CAMPISI WAY, SUITE 370, CAMPBELL, CA, 95008, US

(73) Assignee: PALO ALTO RESEARCH CENTER INCORPORATED, Palo Alto, CA (US)

(21) Appl. No.: 12/324,571

(22) Filed: Nov. 26, 2008

(51) Int. Cl. H01L 21/311

(52) U.S. Cl. 438/694; 257/E21.249

(57) ABSTRACT

Techniques are disclosed for surface texturing multicrystalline silicon using drop jetting technology to form mask or etch patterns on a surface of a multicrystalline silicon substrate.

### BACKGROUND

The subject disclosure is generally directed to texturing a surface of a multicrystalline silicon using drop jetting technology such as ink jet printing technology.

Surface texturing for more efficient light trapping can increase conversion efficiency of multicrystalline silicon solar cells. However, known techniques for surface texturing multicrystalline silicon can be difficult and/or complex.

### BRIEF DESCRIPTION OF DRAWINGS

FIG. 1 is a schematic block diagram of a drop jetting system that can be used in the disclosed surface texturing techniques.

FIGS. 2, 3 and 4 are schematic transverse view illustrating an implementation of a technique for texturing a surface of a muliticrystalline silicon substrate.

FIGS. 5, 6 and 7 are schematic transverse view illustrating an implementation of another technique for texturing a surface of a muliticrystalline silicon substrate.

FIGS. 8, 9, 10, 11, 12 and 13 are schematic transverse view illustrating an implementation of a further technique for texturing a surface of a muliticrystalline silicon substrate.

FIG. 14 is a schematic transverse view illustrating a solar cell that can be produced pursuant to further processing of a muliticrystalline silicon substrate that is selectively surface textured using the disclosed techniques.

### DETAILED DESCRIPTION

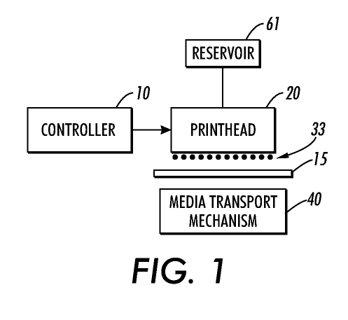

FIG. 1 is a schematic block diagram of an embodiment of a drop on demand liquid drop emitting or jetting system, such as a liquid jet printing or depositing system, that includes a controller 10 and a printhead 20 that can include a plurality of addressable drop emitting drop generators for emitting or depositing drops of liquid 33 onto a receiver substrate 15. A transport mechanism 40 can be employed to move the substrate 15 relative to the printhead 20. The printhead 20 receives liquid from at least one liquid containing reservoir 61 that can be attached to the printhead 20 or separate from the printhead and fluidically connected thereto by an appropriate fluidic connection such as flexible tubing.

The printhead 20 can comprise a piezoelectric jetting device or a thermal or bubble jetting device. For convenience, using a drop on demand liquid drop jetting system such as that schematically depicted in FIG. 1 can sometimes be referred to as using ink jet, or ink jet printing, to apply or deposit material on the substrate 15.

A drop on demand liquid drop jetting system such as that schematically depicted in FIG. 1 can be employed to surface texture multicrystalline silicon (mc-Si for convenience), for example for use as solar cells. By way of illustrative example, drop on demand ink jet printing technology can be suitably modified to deposit or “print” masking materials or etching materials as discussed herein.

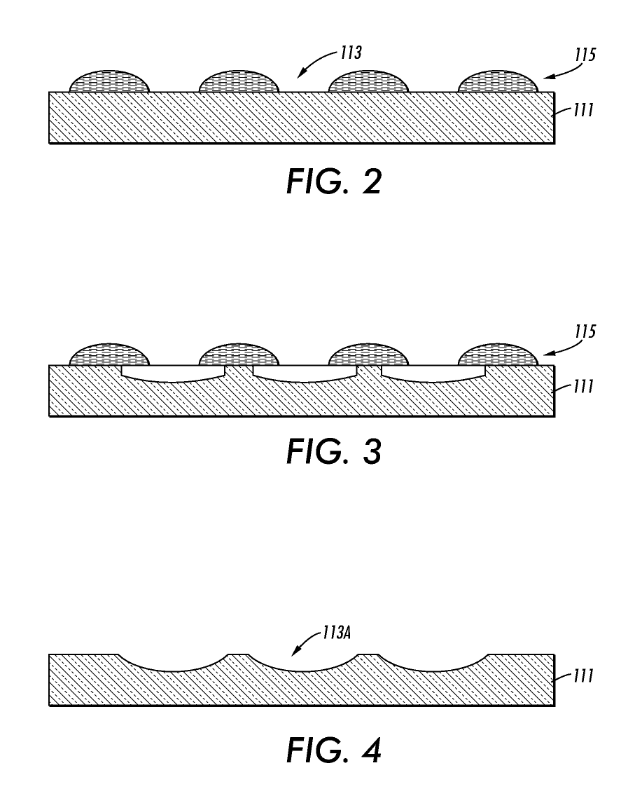

FIGS. 2, 3 and 4 are schematic transverse cross-sectional views illustrating various stages in texturing a predetermined surface 113 of a mc-Si substrate 111.

In FIG. 2, a patterned mask 115 is formed on the predetermined surface 113 of the mc-Si substrate 111 using drop on demand liquid drop jetting, whereby for example a patterned mask is deposited or “printed” on the predetermined mc-Si surface using a drop on demand liquid drop jetting system that jets drops of a suitable masking material. An example of suitable masking materials would be a wax that is configured to be in a liquid state during printing or jetting and freezes to a solid state after being printed on the predetermined mc-Si surface.

In FIG. 3, the masked surface of the mc-Si substrate 111 is etched, for example wet etched using an appropriate wet etching material such as a suitable mixture of nitric acid (HNO₃) and hydrofluoric acid (HF). By way of illustrative example, wet etching can be accomplished by spraying liquid etching solution on the masked surface 113.

Alternatively, dry etching techniques, such as plasma etching and reactive ion etching (RIE) can be employed.

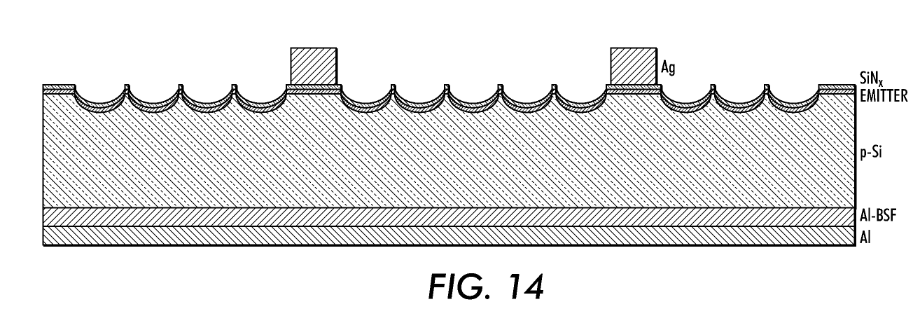

In FIG. 4, the patterned mask 115 is removed to expose a selectively textured surface 113A. As described further herein, a multicrystalline silicon substrate having a selectively textured surface can be further processed to produce a solar cell as schematically depicted in FIG. 14.

Alternatively, the patterned mask 115 can comprise a masking material that can be etched away generally simultaneously with the surface 113 of the mc-Si substrate 111, in which case the structure of FIG. 4 would be produced after etching. Suitable masking materials that can be wet etched simultaneously with the silicon include wax type masking materials that contain alkanes, esters, and/or other suitable chemicals.

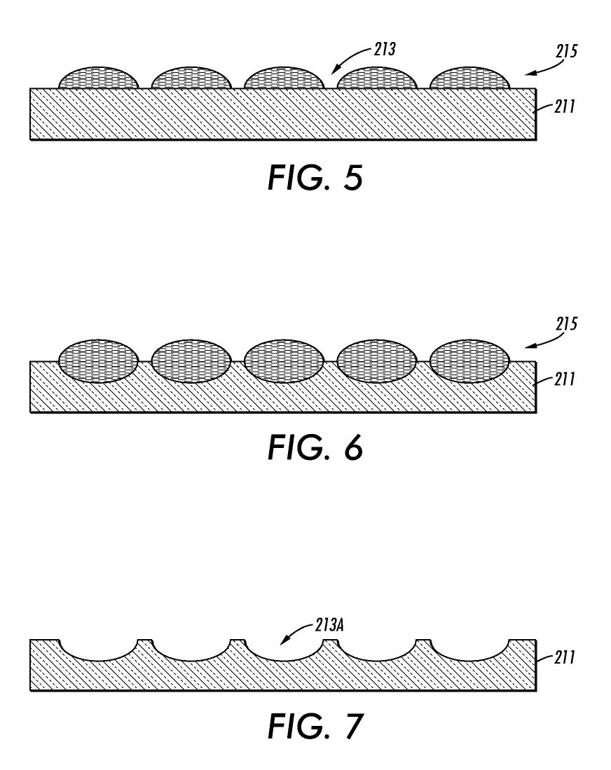

FIGS. 5, 6 and 7 are schematic transverse cross-sectional views illustrating various stages in texturing a predetermined surface 213 of a mc-Si substrate 211.

In FIG. 5, a patterned etching layer 215 is formed on the predetermined surface 213 of the mc-Si substrate 211 using drop on demand liquid drop jetting, whereby for example a patterned etching layer is deposited or “printed” on the predetermined mc-Si surface using a drop on demand liquid drop jetting system that jets a suitable etching material. Examples of suitable etching materials include silicon etching paste available from Merck and/or acid based pastes.

In FIG. 6, the etching layer is allowed to etch the surface of the mc-Si substrate 211 for an appropriate amount of time to achieve the desired amount of etching. Optionally, the etching layer 215 and the surface 213 can be heated while etching, for example by radiant heating or by placing the structure comprising the substrate 211 and the etching layer 215 in an oven or a belt furnace.

In FIG. 7, the patterned etching layer 215 is removed to expose a selectively textured surface 213A. As described further herein, a multicrystalline silicon substrate having a selectively textured surface can be further processed to produce a solar cell as schematically depicted in FIG. 14.

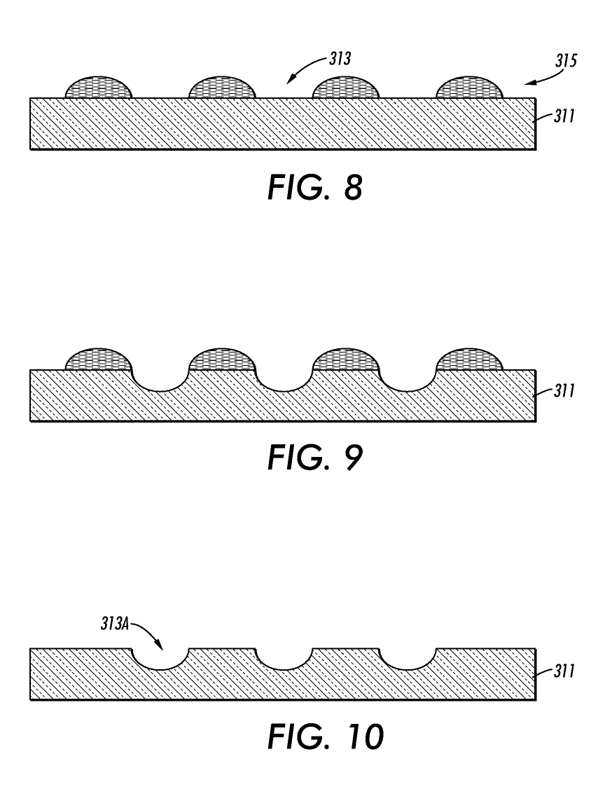

FIGS. 8, 9, 10, 11, 12 and 13 are schematic transverse cross-sectional views illustrating various stages in texturing a predetermined surface 313 of a mc-Si substrate 311.

In FIG. 8, a first patterned mask 315 having a first mask pattern is formed on the predetermined surface 313 of the mc-Si substrate 311 using drop on demand liquid drop jetting, whereby for example a patterned mask is “printed” on the predetermined mc-Si surface using a drop on demand liquid drop jetting system that jets a suitable masking material. Examples of suitable masking materials include a wax that is configured to be in a liquid state during printing or jetting and freezes to a solid state after being printed on the predetermined mc-Si surface.

In FIG. 9, the masked surface of the mc-Si substrate 311 is etched, for example wet etched or dry etched.

In FIG. 10, the first patterned mask 315 is removed to expose a partially textured surface 313A. Alternatively, the patterned mask 315 can comprise a masking material that can be etched away generally simultaneously with the exposed portions of the surface 313 of the mc-Si substrate 311, in which case the structure of FIG. 10 would be produced after etching.

In FIG. 11, a second patterned mask 325 having a second mask pattern is formed on the predetermined surface 313 of the mc-Si substrate 311 using drop on demand liquid drop jetting, whereby for example a patterned mask is “printed” on the predetermined mc-Si surface using a drop on demand liquid drop jetting system that jets a suitable masking material. For example, the second mask pattern covers at least some of the regions that were etched using the first mask 315, so as to leave unmasked at least some portions of the regions that had been protected by the first mask.

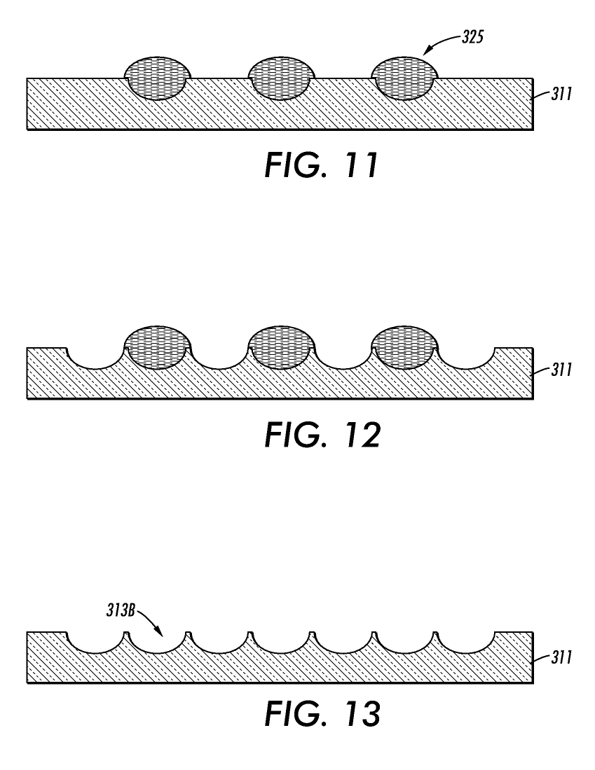

In FIG. 12, the masked partially textured surface of the mc-Si substrate 311 is etched, for example wet etched or dry etched.

In FIG. 13, the second patterned mask 325 is removed to expose a selectively textured surface 313B. Alternatively, the patterned mask 325 can comprise a masking material that can be etched away generally simultaneously with the exposed portions of the surface 313A of the mc-Si substrate 311, in which case the structure of FIG. 13 would be produced after etching.

FIG. 14 is a schematic sectional view of a solar cell that can be made pursuant to further processing of a p-type multicrystalline silicon substrate that has been selectively surface textured pursuant to the foregoing techniques. The solar cell includes an n+ emitter layer in the portion of the substrate that includes the selectively textured surface and an antireflection layer such as silicon nitride (SiNx) disposed on the selectively textured surface. By way of illustrative examples, the n+ emitter layer can be formed by diffusing donor doping material, while the SiNx antireflection layer can be formed by known techniques such as chemical vapor deposition or physical vapor deposition. Metal electrodes such as silver gridline or busbar can be deposited on the non-textured portions of the selectively textured surface after formation of the emitter layer and the antireflection layer. For completeness, the solar cell of FIG. 14 is shown as including an AL-BSF (aluminum Back Surface Field) layer and an Al backside electrode layer on the back surface of the substrate. The Al backside electrode layer can be deposited for example by screen printing, and the AL-BSF layer will be formed during the electrode firing process when the screen printed Al reacts with the Si substrate to form the AL-BSF layer.

Depending on implementation, the disclosed techniques can be embedded/integrated into existing in-line wet processing systems.

The claims, as originally presented and as they may be amended, encompass variations, alternatives, modifications, improvements, equivalents, and substantial equivalents of the embodiments and teachings disclosed herein, including those that are presently unforeseen or unappreciated, and that, for example, may arise from applicants/patentees and others. Unless specifically recited in a claim, steps or components of claims should not be implied or imported from the specification or any other claims as to any particular order, number, position, size, shape, angle, color, or material.

What is claimed is:

1. A method of texturing a surface of a multicrystalline silicon substrate comprising:
drop on demand printing a patterned mask on a surface of a multicrystalline silicon substrate; and
etching the masked surface of the multicrystalline silicon substrate to form an etched surface.

2. The method of claim 1 wherein drop on demand printing a patterned mask comprises thermally drop on demand printing a patterned mask on a surface of a multicrystalline silicon substrate.

3. The method of claim 1 wherein drop on demand printing a patterned mask comprises piezoelectrically drop on demand printing a patterned mask on a surface of a multicrystalline silicon substrate.

4. The method of claim 1 wherein drop on demand printing a patterned mask comprises drop on demand printing a patterned wax mask.

5. The method of claim 1 wherein etching the masked surface comprises wet etching the masked surface to form an etched surface.

6. The method of claim 1 wherein etching the masked surface comprises spraying liquid etching material on the masked surface.

7. The method of claim 1 wherein etching the masked surface comprises dry etching the masked surface to form an etched surface.

8. The method of claim 1 etching the masked surface comprises etching exposed areas of the surface and etching the patterned mask whereby separate removal of the patterned mask can be avoided.

9. A method of texturing a surface of a multicrystalline silicon substrate comprising:
using a drop jetting apparatus to form a patterned mask on a surface of a multicrystalline silicon substrate; and
etching the masked surface of the multicrystalline silicon substrate to form an etched surface.

10. The method of claim 9 using a drop jetting apparatus to form a patterned mask comprises using a thermal drop on demand apparatus to form a patterned mask on a surface of a multicrystalline silicon substrate.

11. The method of claim 9 wherein using a drop jetting apparatus to form a patterned mask comprises using a piezoelectric drop on demand apparatus to form a patterned mask on a surface of a multicrystalline silicon substrate.

12. The method of claim 9 wherein using a drop jetting apparatus to form a patterned mask comprises using a drop on demand apparatus to form a patterned wax mask on a surface of a multicrystalline silicon substrate.

13. The method of claim 9 wherein etching the masked surface comprises wet etching the masked surface to form an etched surface.

14. The method of claim 9 wherein etching the masked surface comprises spraying liquid etching material on the masked surface.

15. The method of claim 9 wherein etching the masked surface comprises dry etching the masked surface to form an etched surface.

16. The method of claim 9 etching the masked surface comprises etching exposed areas of the surface and etching the patterned mask whereby separate removal of the patterned mask can be avoided.

17. A method of texturing a surface of a multicrystalline silicon substrate comprising:
drop on demand printing a patterned etching layer on a surface of a multicrystalline silicon substrate;
allowing the etching layer to etch the surface of the multicrystalline silicon substrate;
cleaning the etched surface of the multicrystalline silicon substrate.

18. The method of claim 17 wherein drop on demand printing comprises piezoelectrically drop on demand printing a patterned etching layer on a surface of a multicrystalline silicon substrate.

19. The method of claim 17 wherein drop on demand printing comprises thermally drop on demand printing a patterned etching layer on a surface of a multicrystalline silicon substrate.

20. A method of texturing a surface of a multicrystalline silicon substrate comprising:
using a drop jetting apparatus to form a patterned etching layer on a surface of a multicrystalline silicon substrate;
allowing the etching layer to etch the surface of the multicrystalline silicon substrate;
cleaning the etched surface of the multicrystalline silicon substrate.

21. The method of claim 20 wherein using a drop jetting apparatus comprises using a piezoelectric drop jetting apparatus to form a patterned etching layer on a surface of a multicrystalline silicon substrate.

22. The method of claim 20 wherein using a drop jetting apparatus comprises using a thermal drop jetting apparatus to form a patterned etching layer on a surface of a multicrystalline silicon substrate.

23. A method of texturing a surface of a multicrystalline silicon substrate comprising:
drop on demand printing a first mask having a first mask pattern on a surface of a multicrystalline silicon substrate;
etching the masked surface of the multicrystalline silicon substrate to form an etched surface;
removing the first mask;
drop on demand printing a second mask having a second mask pattern on the etched surface, wherein the second mask pattern is different from the first mask pattern;
etching the masked surface of the multicrystalline silicon substrate to form a further etched surface;
removing the second mask.

24. The method of claim 23 wherein drop on demand printing a first mask having a first mask pattern comprises piezoelectrically drop on demand printing a first mask on a surface of a multicrystalline silicon substrate, and wherein drop on demand printing a second mask having a second mask pattern on the etched surface comprises piezoelectrically drop on demand printing a second mask having a second mask pattern on the etched surface, wherein the second mask pattern is different from the first mask pattern.

25. The method of claim 23 wherein drop on demand printing a second mask having a second mask pattern on the etched surface comprises drop on demand printing a second mask having a second mask pattern on the etched surface, wherein the second mask pattern covers at least some areas of the surface of the multicrystalline silicon substrate that were not covered by the first pattern.

26. The method of claim 23 wherein drop on demand printing a second mask having a second mask pattern on the etched surface comprises drop on demand printing a second mask having a second mask pattern on the etched surface, wherein the second mask pattern leaves exposed at least some areas of the surface of the multicrystalline silicon substrate that were not etched using the first mask.

27. The method of claim 23 wherein etching the masked surface comprises etching exposed areas of the surface and etching the patterned mask whereby separate removal of the patterned first and/or second mask can be avoided.
